(19) United States
(12) Patent Application Publication
(10) Pub. No.: US 2026/0114242 A1
(43) Pub. Date: Apr. 23, 2026

(54) PHOTORESIST COMPOSITIONS AND METHODS OF MANUFACTURING SEMICONDUCTOR DEVICES USING THE SAME

(71) Applicant: Samsung Electronics Co., Ltd., Suwon-si (KR)

(72) Inventors: Kunyoung Lee, Suwon-si (KR); Sounghyun Jun, Suwon-si (KR); Juhyeon Park, Suwon-si (KR)

(21) Appl. No.: 19/317,704

(22) Filed: Sep. 3, 2025

(30) Foreign Application Priority Data
Oct. 17, 2024 (KR) 10-2024-0142341

(51) Int. Cl. H01L 21/027; G03F 7/004; G03F 7/36

(52) U.S. Cl. CPC H10P 76/2041; G03F 7/0042; G03F 7/36

(57) ABSTRACT

A method of manufacturing a semiconductor device includes forming a first resist layer on a substrate, forming a second resist layer on the first resist layer, exposing a first region of the second resist layer, forming a photoresist pattern by performing a heat treatment on the second resist layer to remove an unexposed second region of the second resist layer, and processing the first resist layer using the photoresist pattern.

### CROSS-REFERENCE TO RELATED APPLICATION(S)

This U.S. non-provisional application claims priority under 35 USC § 119 to Korean Patent Application No. 10-2024-0142341, filed on Oct. 17, 2024, in the Korean Intellectual Property Office, the disclosure of which is herein incorporated by reference in its entirety.

### TECHNICAL FIELD

Example embodiments relate to a photoresist composition and a method of manufacturing a semiconductor device using the same.

### BACKGROUND

Advancements in electronic technology have led to rapid progress in miniaturizing semiconductor devices. Such miniaturization requires photolithography processes capable of forming micropatterns.

A photolithography process typically includes an exposure process and a development process. During the exposure process, light of a specific wavelength is irradiated to a photoresist layer to induce a change in chemical structure of the photoresist layer. The development process leverages a difference in solubility between exposed and unexposed areas of the photoresist layer, selectively removing either the exposed or unexposed areas using a developer.

As patterns formed in a photolithography process become finer, photoresist patterns are more prone to collapse or loss due to a developer during a development process.

### SUMMARY

Example embodiments provide a photoresist composition that reduces or prevents the collapse of photoresist patterns and defects caused by residues of a photoresist layer during development in a photolithography process, and a method of manufacturing a semiconductor device using the photoresist composition.

Example embodiments provide a method of manufacturing a semiconductor device with a simplified process and improved productivity.

According to an example embodiment, a method of manufacturing a semiconductor device includes forming a first resist layer on a substrate, forming a second resist layer on the first resist layer, exposing a first region of the second resist layer, forming a photoresist pattern by performing a heat treatment on the second resist layer to remove an unexposed second region of the second resist layer, and processing the first resist layer using the photoresist pattern.

According to an example embodiment, a method of manufacturing a semiconductor device includes forming a first resist layer on a substrate, forming a second resist layer on the first resist layer, exposing a first region of the second resist layer, performing a heat treatment on the second resist layer to form a photoresist pattern, and processing an underlying layer using the photoresist pattern. The forming of the photoresist pattern may include performing a first heat treatment at a temperature of 110° C. to 180° C. to crosslink the first region and the first resist layer and performing a second heat treatment at a temperature of 200° C. to 280° C. to remove an unexposed second region of the second resist layer. The second resist layer may include an organometallic compound, an additive, and a solvent. The organometallic compound may include two or more hydrocarbon groups covalently bonded to the metal and one or more halide groups F, Cl, Br, or I covalently bonded to the metal. The metal may be polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), or astatine (At). The hydrocarbon groups may each be independently a substituted or unsubstituted C1-C12 alkyl group, a substituted or unsubstituted C5-C8 cycloalkyl group, or a substituted or unsubstituted C6-C14 aryl group. In some embodiments, a boiling point of the organometallic compound may be higher than a temperature at which the first heat treatment is performed, and lower than a temperature at which the secondary heat treatment is performed.

According to an example embodiment, a photoresist composition includes an organometallic compound, an additive, and a solvent. The organometallic compound may include tetravalent tin (Sn) as a central metal atom, two or more hydrocarbon groups covalently bonded to the tin, and one or more halide groups F, Cl, Br, or I covalently bonded to the tin. The hydrocarbon groups may each be independently a substituted or unsubstituted C1-C12 alkyl group, a substituted or unsubstituted C5-C8 cycloalkyl group, or a substituted or unsubstituted C6-C14 aryl group.

### BRIEF DESCRIPTION OF DRAWINGS

FIG. 1 is a flowchart illustrating a method of manufacturing a semiconductor device according to an example embodiment.

FIG. 2 is a flowchart illustrating a method of manufacturing a semiconductor device according to an example embodiment.

FIG. 3 is a plan view illustrating a method of manufacturing a semiconductor device according to an example embodiment.

FIGS. 4A to 4E are cross-sectional views corresponding to line A-A′ of FIG. 3 and illustrating a method of manufacturing a semiconductor device according to an example embodiment.

### DETAILED DESCRIPTION

The present disclosure may be modified in various ways, and may have various embodiments, among which specific embodiments will be described in detail with reference to the accompanying drawings. However, it should be understood that the description of the specific embodiments of the present disclosure is not intended to limit the present disclosure to a particular mode of practice, and that the present disclosure is to cover all modifications, equivalents, and substitutes included in the spirit and technical scope of the present disclosure.

In the present disclosure, the term “substituted” refers to the replacement of a hydrogen atom with deuterium, a halogen group, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C14 aryl group, a C1 to C20 alkoxy group, or a cyano group. The term “unsubstituted” means that a hydrogen atom remains unchanged, without replacement with any substituent.

In the present disclosure, the term “alkyl group” refers to a straight-chain or branched aliphatic hydrocarbon group, unless otherwise defined. The alkyl group may be a “saturated alkyl group” containing no double or triple bonds. The alkyl group may be a C1 to C20 alkyl group. For example, the alkyl group may be a C1 to C10 alkyl group or a C1 to C6 alkyl group. For example, a C1 to C4 alkyl group means an alkyl chain with 1 to 4 carbon atoms, and may refer to a selection from the group consisting of methyl, ethyl, propyl, isopropyl, n-butyl, isobutyl, sec-butyl, or t-butyl. For example, the alkyl group may refer to a methyl group, ethyl group, propyl group, isopropyl group, butyl group, isobutyl group, t-butyl group, pentyl group, or hexyl group.

In the present disclosure, the term “cycloalkyl group” may refer to a monovalent cyclic aliphatic hydrocarbon group, unless otherwise defined.

In the present disclosure, the term “aryl group” refers to a substituent where all atoms of a cyclic substituent possess p-orbitals, and the p-orbitals form a conjugation. The aryl group may include monocyclic or fused ring polycyclic (for example, rings sharing adjacent pairs of carbon atoms) functional groups.

In the present disclosure, the term “halide group” may refer to a fluorine (F), chlorine (Cl), bromine (Br), or iodine (I) functional group, unless otherwise defined.

An example embodiment relates to a photoresist composition and a method of forming a photolithography pattern using the photoresist composition. In an example embodiment, a method of forming a pattern using the photolithography may be employed in the process of manufacturing a semiconductor device. Therefore, the following description will be provided in the context of a method of manufacturing a semiconductor device.

Hereinafter, a photoresist composition according to an example embodiment will be described in detail, followed by a description of a method of manufacturing a semiconductor device using the photoresist composition.

The photoresist composition according to an example embodiment may include an organometallic compound, an additive, and a solvent.

The organometallic compound according to an example embodiment may be an organic compound with a structure where a functional group containing carbon (C) is bonded to a central metal atom.

In an example embodiment, the organometallic compound may be a photosensitive material capable of inducing a photochemical reaction upon irradiation by a KrF excimer laser (248 nm), an ArF excimer laser (193 nm), an F2 excimer laser (157 nm), or extreme ultraviolet (EUV) light (13.5 nm).

In an example embodiment, the organometallic compound may be used as a non-chemically amplified photoresist material. For example, the organometallic compound may be a material that directly forms a photoresist pattern without a chemical amplification reaction through a catalyst after an exposure process, in a photolithography process. For example, the organometallic compound may not exhibit chemical amplification.

In an example embodiment, the central metal atom of the organometallic compound may be a metal with significant EUV absorption, such as polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), or astatine (At), but example embodiments are not limited to these.

In an example embodiment, the central metal atom of the organometallic compound may be tetravalent tin (Sn). Tin (Sn) strongly absorbs EUV light at 13.5 nm, so that an organometallic compound containing tin (Sn) may exhibit improved sensitivity to high-energy light. Accordingly, the organometallic compound according to an example embodiment may include tin as a central atom, resulting in improved photosensitivity.

In an example embodiment, the organometallic compound may have a structure in which an organic functional group and a halide group are covalently bonded to the central metal atom. The organometallic compound may include, for example, a metal as a central atom, two or more hydrocarbon groups covalently bonded to the metal, and one or more halide groups covalently bonded to the metal. The hydrocarbon groups may each be independently a substituted or unsubstituted C1-C12 alkyl group, a substituted or unsubstituted C5-C8 cycloalkyl group, or a substituted or unsubstituted C6-C14 aryl group, and the halide group may be fluorine (F), chlorine (Cl), bromine (Br), or iodine (I).

In an example embodiment, the organometallic compound may include a compound represented by the following Chemical Formula 1.

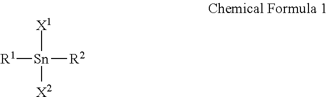

In Chemical Formula 1, R¹ and R² are each independently a substituted or unsubstituted C1-C12 alkyl group, a substituted or unsubstituted C5-C8 cycloalkyl group, or a substituted or unsubstituted C6-C14 aryl group, and X¹ and X² are each independently one of the halide groups F, Cl, Br, or I.

The compound represented by Chemical Formula 1 may include tetravalent tin (Sn) as a central metal atom, two hydrocarbon groups covalently bonded to the tin, and two halide groups covalently bonded to the tin. The hydrocarbon groups may each be independently substituted or unsubstituted C1-C12 alkyl groups, substituted or unsubstituted C5-C8 cycloalkyl groups, or substituted or unsubstituted C6-C14 aryl groups, and the halide group may be fluorine (F), chlorine (Cl), bromine (Br), or iodine (I).

For example, the organometallic compound may include at least one of the compounds selected from the following:

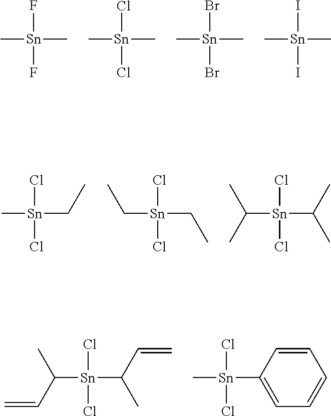

In an example embodiment, three hydrocarbon groups may be covalently bonded to a single central metal atom of the organometallic compound. For example, the organometallic compound may include a compound represented by the following Chemical Formula 2.

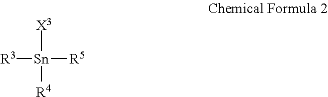

In Chemical Formula 2, R³ to R⁵ are each independently substituted or unsubstituted C1-C12 alkyl groups, substituted or unsubstituted C5-C8 cycloalkyl groups, or substituted or unsubstituted C6-C14 aryl groups, and X³ is one of the halide groups F, Cl, Br, or I.

In an example embodiment, the organometallic compound may be a photosensitive material exposed to light and cleaved using a chain scission mechanism. For example, when the organometallic compound is exposed to light of a specific wavelength, the bond between tin (Sn) and R¹ and/or R² in Chemical Formula 1 may be cleaved. Bond dissociation energy between tin (Sn) and R¹ and/or R² may be lower than bond dissociation energy between tin (Sn) and X¹ and/or X². Therefore, when the organometallic compound is exposed to light having a wavelength intensity higher than the bond dissociation energy between tin (Sn) and R¹ and/or R² and lower than the bond dissociation energy between tin (Sn) and X¹ and/or X², only the bond between tin (Sn) and R¹ and/or R² may be cleaved, while the bond between tin (Sn) and X¹ and/or X² in Chemical Formula 1 is maintained. Such a principle allows selective cleavage of the bond between tin (Sn) and R¹ and/or R².

Similarly, when the organometallic compound is exposed to light of a specific wavelength, the bond between the central metal atom in Chemical Formula 2 and R³, R⁴, and/or R⁵ in Chemical Formula 2 may be selectively cleaved.

In an example embodiment, the organometallic compound may include a photosensitive polymer. For example, the photosensitive polymer may be a homopolymer including a plurality of single monomers. For example, the photosensitive polymer may be a homopolymer including the monomers of Chemical Formula 1 or the monomers of Chemical Formula 2. Also, the single monomers may be acrylate-based monomers.

In an example embodiment, the photosensitive polymer may be a copolymer including two or more monomers. For example, the photosensitive polymer may be a copolymer polymerized from at least one of the monomers of Chemical Formula 1 and at least one of the monomers of Chemical Formula 2. Also, the two or more monomers may each be independently selected from either an acrylate-based monomer or a styrene-based monomer. The photosensitive polymer may be, for example, polymethylmethacrylate (PMMA), or a copolymer of α-chloromethacrylate and α-methylstyrene.

In the photoresist composition according to an example embodiment, the organometallic compound may be included in an amount of about 0.1 wt % to about 90 wt %, or any range therein, for example, about 40 wt % to about 95 wt %, about 45 wt % to about 90 wt %, or about 50 wt % to about 90 wt %, based on 100 wt % of the photoresist composition.

In an example embodiment, the photoresist composition may include an additive. The additive may include various types of substances and improve physical and chemical properties of the photoresist, enabling formation of a stable and finer photoresist pattern.

In an example embodiment, the additive may include at least one selected from a crosslinker, a surfactant, a dispersant, a hygroscopic agent, a coupling agent, a leveling agent, and an organic acid.

A crosslinker may enhance the crosslinking between the organometallic compound and the adhesive during polymerization by heat treatment. When a crosslinker is used, physical properties of a crosslinked polymer may vary depending on the presence or absence of the crosslinker, the type of crosslinker, or the content of the crosslinker. For example, an etch rate of the crosslinked polymer may vary depending on the presence or absence of the crosslinker, the type of crosslinker, or the content of the crosslinker.

The crosslinker may be at least one selected from polyfunctional (meth)acrylates, cyclic ether-containing compounds, glycol urils, diisocyanates, melamines, benzoguanamines, polynuclear phenols, polyfunctional thiol compounds, polysulfide compounds, and sulfide compounds, but example embodiments are not limited thereto.

The polyfunctional (meth)acrylates may be compounds having two or more (meth)acryloyl groups. The polyfunctional (meth)acrylates may include, for example, polyfunctional (meth)acrylates obtained by reacting aliphatic polyhydroxy compounds with (meth)acrylic acid, caprolactone-modified polyfunctional (meth)acrylates, alkylene oxide-modified polyfunctional (meth)acrylates, polyfunctional urethane (meth)acrylates obtained by reacting (meth)acrylates having hydroxyl groups (—OH) with polyfunctional isocyanates, or polyfunctional (meth)acrylates having carboxyl groups obtained by reacting (meth)acrylates having hydroxyl groups with acid anhydrides.

When the photoresist composition according to an example embodiment contains a crosslinker, the crosslinker may be included in an amount of 1 part by weight to 60 parts by weight, or any range therein, for example, 2 parts by weight to 50 parts by weight, or 3 parts by weight to 40 parts by weight, based on 100 parts by weight of the organometallic compound, but example embodiments are not limited thereto.

The surfactant may improve coating uniformity and wettability of the photoresist composition. In an example embodiment, the surfactant may include sulfuric acid ester salts, sulfonic acid salts, phosphoric acid esters, soaps, amine salts, quaternary ammonium salts, polyethylene glycol, alkylphenol ethylene oxide adducts, polyhydric alcohols, nitrogen-containing vinyl polymers, or combinations thereof, but example embodiments are not limited thereto.

The surfactant may be, for example, at least one selected from fluoroalkylbenzene sulfonates, fluoroalkyl carboxylates, fluoroalkyl polyoxyethylene ethers, fluoroalkyl ammonium iodides, fluoroalkyl betaines, fluoroalkyl sulfonates, diglycerin tetrakis(fluoroalkyl polyoxyethylene ethers), fluoroalkyl trimethyl ammonium salts, fluoroalkyl amino sulfonates, polyoxyethylene nonylphenyl ether, polyoxyethylene octylphenyl ether, polyoxyethylene alkyl ethers, polyoxyethylene lauryl ether, polyoxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene lauryl amine, sorbitan laurate, sorbitan palmitate, sorbitan stearate, sorbitan oleate, sorbitan fatty acid esters, polyoxyethylene sorbitan laurate, polyoxyethylene sorbitan palmitate, polyoxyethylene sorbitan stearate, polyoxyethylene sorbitan oleate, polyoxyethylene naphthyl ether, alkylbenzene sulfonates, and alkyldiphenylether disulfonates, but example embodiments are not limited thereto.

When the photoresist composition according to an example embodiment contains a surfactant, the surfactant may be included in an amount of 0.001 parts by weight to 1 part by weight, or any range therein, for example, 0.001 parts by weight to 0.1 parts by weight, or 0.01 parts by weight to 0.1 parts by weight, based on 100 parts by weight of the organometallic compound, but example embodiments are not limited thereto.

The dispersant may serve to uniformly disperse each constituent component of the photoresist composition within the photoresist composition. In an example embodiment, the dispersant may include epoxy resin, polyvinyl alcohol, polyvinyl butyral, polyvinylpyrrolidone, glucose, sodium dodecyl sulfate, sodium citrate, oleic acid, linoleic acid, or combinations thereof, but example embodiments are not limited thereto.

When the photoresist composition according to an example embodiment includes a dispersant, the dispersant may be included in an amount of about 0.001 wt % to about 5 wt %, or any range therein, based on 100 wt % of the photoresist composition.

A hygroscopic agent may serve to prevent adverse effects caused by moisture in the photoresist composition. For example, the hygroscopic agent may serve to prevent a metal included in the photoresist composition from being oxidized by moisture. In an example embodiment, the hygroscopic agent may include polyoxyethylene nonylphenyl ether, polyethylene glycol, polypropylene glycol, polyacrylamide, or combinations thereof, but example embodiments are not limited thereto.

When the photoresist composition according to an example embodiment includes a hygroscopic agent, the hygroscopic agent may be included in an amount of about 0.001 wt % to about 10 wt %, or any range therein, based on 100 wt % of the photoresist composition.

The coupling agent may be an adhesion promoter for improving the adhesion between a photoresist layer and a substrate. For example, the coupling agent may serve to improve the adhesion to the substrate when the photoresist composition is coated on the substrate. In exemplary embodiments, the coupling agent may include a silane coupling agent. The coupling agent may be, for example, a silane coupling agent. More specifically, the silane coupling agent may be vinyltrimethoxysilane, vinyltriethoxysilane, vinyltrichlorosilane, vinyltris(β-methoxyethoxy) silane, 3-methacryloxypropyltrimethoxysilane, 3-acryloxypropyltrimethoxysilane, 1 p-styryl trimethoxysilane, 3-methacryloxypropylmethyldimethoxysilane, 3-methacryloxypropylmethyldiethoxysilane, 2 or trimethoxy [3-(phenylamino) propyl]silane, but example embodiments are not limited thereto.

When the photoresist composition according to an example embodiment includes the coupling agent, the coupling agent may be included in an amount of about 0.001 wt % to about 5 wt %, or any range therein, based on 100 wt % of the photoresist composition.

The leveling agent is a substance used to improve coating smoothness during printing. Any known leveling agent, available through commercial methods, may be used as the leveling agent.

The organic acid may be p-toluenesulfonic acid, benzenesulfonic acid, p-dodecylbenzenesulfonic acid, 1,4-naphthalenedisulfonic acid, methanesulfonic acid, fluorinated sulfonium salt, malonic acid, citric acid, propionic acid, methacrylic acid, oxalic acid, lactic acid, glycolic acid, succinic acid, or combinations thereof, but example embodiments are not limited thereto.

The solvent included in the photoresist composition according to an example embodiment may include an organic solvent. The organic solvent may include at least one of an ether, an alcohol, a glycol ether, an aromatic hydrocarbon compound, a ketone, and an ester, but example embodiment are not limited thereto.

For example, the organic solvent may be ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbinol: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methoxyethoxy propionate, ethoxyethoxy propionate, or combinations thereof. The solvent may be used either alone or in combination of at least two different types.

In the photoresist composition according to an example embodiment, when the solvent consists of only an organic solvent, the photoresist composition may further include water. A content of the water in the photoresist composition may be about 0.001 wt % to about 0.1 wt %, or any range therein, based on 100 wt % of the photoresist composition.

In the photoresist composition according to an example embodiment, the content of the solvent may be the remaining amount excluding the content of main constituent components such as the organometallic compound.

According to an example embodiment, the photoresist composition may contain arbitrary components within a range that does not impair the effects of the present disclosure. When the photoresist composition includes components such as the arbitrary component (for example, resin, basic quencher, or additive), the content of the solvent may be the remaining amount excluding the content of main constituent components and the arbitrary component. For example, the solvent may be included in a content of about 0.1 wt % to about 99 wt %, or any range therein, based on 100 wt % of the photoresist composition.

In an example embodiment, the photoresist composition may further include a basic quencher.

The basic quencher may control the balance of acid and basic substances in the photoresist composition. For example, the basic quencher may suppress the diffusion of acid and unnecessary chemical reactions between metal elements and organic compounds in the photoresist composition. Thus, the structural stability of the organometallic compound in the photoresist composition may be maintained.

In an example embodiment, the basic quencher may include a primary aliphatic amine, a secondary aliphatic amine, a tertiary aliphatic amine, an aromatic amine, a heterocyclic ring-containing amine, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, amides, imides, carbamates, or ammonium salts. The basic quencher may include, for example, triethanolamine, triethylamine, tributylamine, tripropylamine, hexamethyl disilazane, aniline, N-methylaniline, N-ethylaniline, N-propylaniline, N,N-dimethylaniline, N,N-bis(hydroxyethyl) aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or combinations thereof, but example embodiments are not limited thereto.

In the photoresist composition according to an example embodiment, the basic quencher may be included in an amount of about 0.01 wt % to about 5.0 wt %, or any range therein, based on 100 wt % of the photoresist composition, but example embodiments are not limited thereto.

The above-described photoresist composition may be used in the manufacturing of semiconductor devices. For example, the photoresist composition may be used in the manufacturing of integrated circuit devices that requires the formation of patterns with a high aspect ratio. The photoresist composition may be used, for example, in the manufacturing of semiconductor memory devices for forming a micropattern having a width of 5 nm to 100 nm, or any range therein, for example, a micropattern having a width of 5 nm to 80 nm, a micropattern having a width of 5 nm to 70 nm, a micropattern having a width of 5 nm to 50 nm, a micropattern having a width of 5 nm to 40 nm, a micropattern having a width of 5 nm to 30 nm, or a micropattern having a width of 5 nm to 20 nm.

Hereinafter, a method of manufacturing a semiconductor device using the photoresist composition will be described.

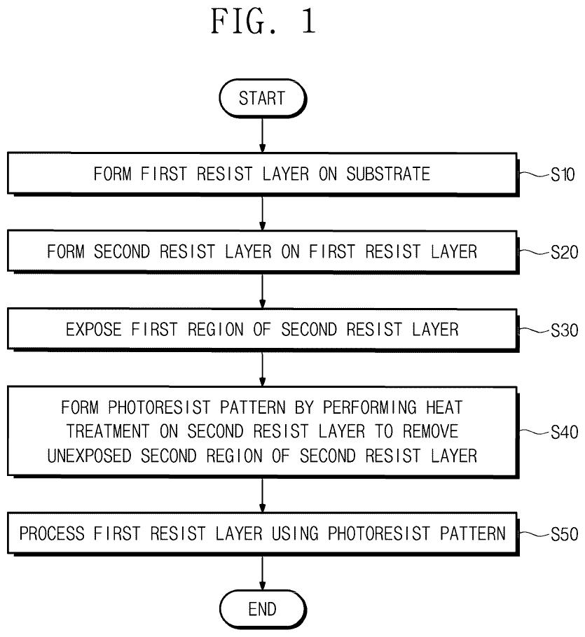

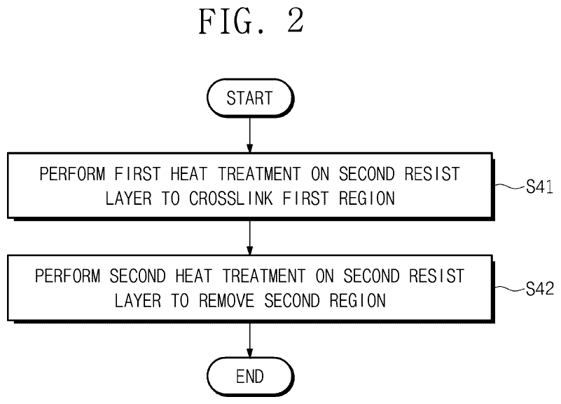

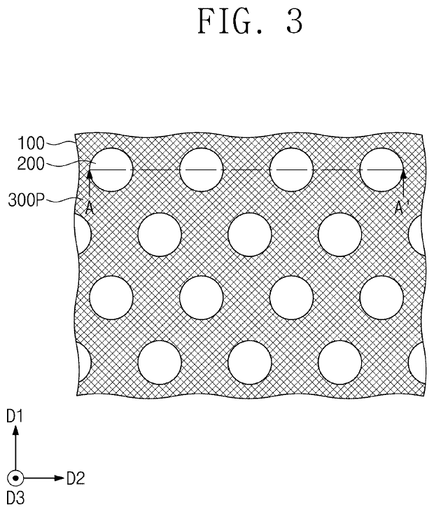

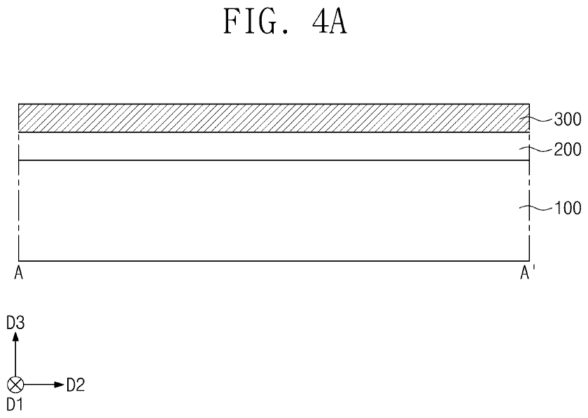

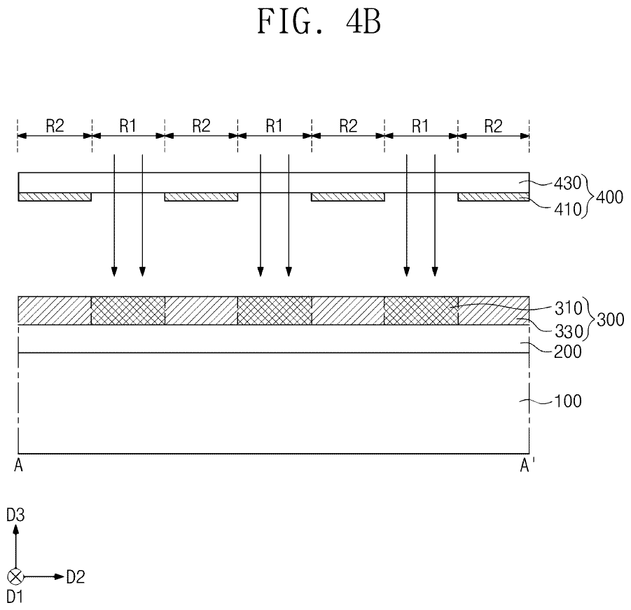

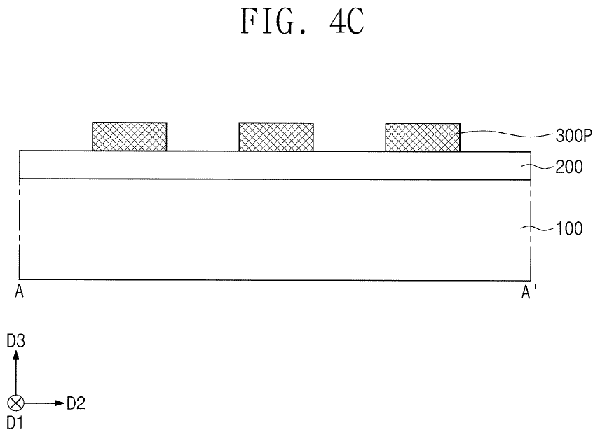

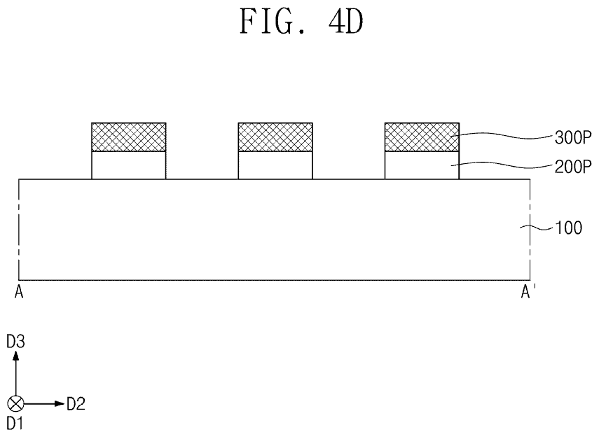

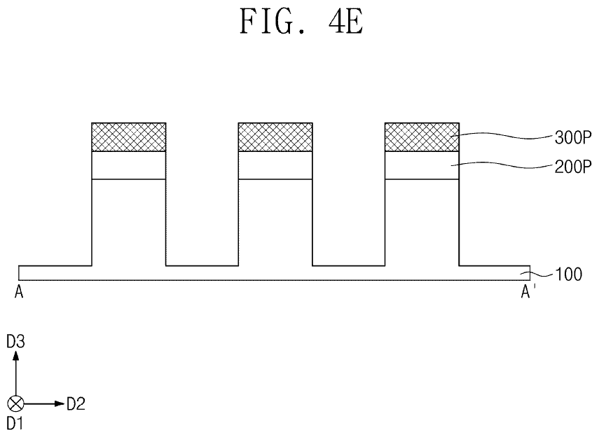

FIG. 1 is a flowchart illustrating a method of manufacturing a semiconductor device according to an example embodiment. FIG. 2 is a flowchart illustrating a method of manufacturing a semiconductor device according to an example embodiment. FIG. 3 is a plan view illustrating a method of manufacturing a semiconductor device according to an example embodiment. FIGS. 4A to 4E are cross-sectional views corresponding to line A-A′ of FIG. 3 and illustrating a method of manufacturing a semiconductor device according to an example embodiment.

Referring to FIGS. 1 and 2, a method of manufacturing a semiconductor device according to an embodiment of the present disclosure may include forming a first resist layer on a substrate (S10), forming a second resist layer on the first resist layer (S20), exposing a first region of the second resist layer (S30), forming a photoresist pattern by performing a heat treatment on the second resist layer to remove an unexposed second region of the second resist layer (S40), and processing the first resist layer using the photoresist pattern (S50). The forming of the photoresist pattern (S40) may include performing a first treatment on the second resist layer to crosslink the first region (S41) and performing a second heat treatment on the second resist layer to remove the second region (S42). This will be described in detail with reference to the accompanying drawings.

Referring to FIGS. 1, 3, and 4A, a substrate 100 may be prepared. The substrate 100 may be an etching target of the photoresist pattern 300P. For example, the substrate 100 may be a material processed in an etching process to obtain a desired pattern shape through a photolithography process. The substrate 100 may include an elemental semiconductor material such as silicon (Si) or germanium (Ge), or a compound semiconductor material such as SiGe, SiC, GaAs, InAs, or InP. However, the substrate 100 is not limited thereto, and may be formed of various materials such as metal, glass, or polymer resin.

In an example embodiment, a thin film may be formed on the substrate 100. The etching target may be the thin film rather than the substrate 100. The thin film may be an insulating layer, a conductive layer, or a semiconductor layer. The thin film may be formed of, for example, metal, alloy, metal carbide, metal nitride, metal oxynitride, metal oxycarbide, semiconductor, polysilicon, oxide, nitride, oxynitride, or combinations thereof, but example embodiments are not limited thereto. In an example embodiment, a coating process of the thin film may be omitted.

In an example embodiment, a bottom anti-reflective coating (BARC) layer may be selectively formed on the substrate 100. The BARC layer may control the scattering of light from a light source used during the exposure process for manufacturing a semiconductor device or absorb light reflected from the substrate 100. The BARC layer may be formed of an organic anti-reflective coating (ARC) material for a KrF excimer laser, an ArF excimer laser, or any other light source. In an example embodiment, the BARC layer may include an organic component having a light-absorbing structure. The light-absorbing structure may be, for example, a hydrocarbon compound having one or more benzene rings or a structure in which benzene rings are fused. In an example embodiment, the BARC layer may be formed to a thickness of about 5 nm to about 100 nm, but example embodiments are not limited thereto. In an example embodiment, the formation of the BARC layer may be omitted.

Then, forming a first resist layer on the substrate S10 may be performed. For example, the first resist layer 200 may be formed on the substrate 100 through drying and heat treatment. The heat treatment may be performed at a temperature of about 100° C. to about 300° C. The first resist layer 200 may function as an adhesive layer to bond a subsequently formed second resist layer 300 to the substrate 100. The first resist layer 200 may include, for example, a polymer resin. Also, the first resist layer 200 may include at least a portion of the additives included in the above-described photoresist composition. In an example embodiment, the formation of the first resist layer 200 may be omitted.

Next, forming a second resist layer on the first resist layer (S20) may be performed. The second resist layer 300 may be formed by coating the above-described photoresist composition on the first resist layer 100. The second resist layer 300 may be in a cured form obtained by coating the photoresist composition and then undergoing a heat treatment process.

For example, the forming of the second resist layer on the first resist layer S20 may include a process of applying the photoresist composition to the first resist layer 200 by spin coating, spray coating, dip coating, aerosol coating, ink-jet printing, or the like, and may include a process of drying the applied photoresist composition to form the second resist layer 300.

Next, a pre-exposure baking (PEB) process may be performed. The pre-exposure baking process may be a process of heating the substrate 100 on which the first and second resist layers 200 and 300 are formed. A solvent in the second resist layer 300 may be removed through the pre-exposure baking process.

Referring to FIGS. 1, 2, and 4B, exposing the first region of the second resist layer (S30) may be performed. For example, an exposure process may be performed to align a photomask 400 on the second resist layer 300, and light may be irradiated onto the second resist layer 300 through the photomask 400.

The light may be in an ultraviolet wavelength range, e.g., between about 13.5 nm and 248 nm. The light in the ultraviolet wavelength range may be, for example, one light selected from a KrF excimer laser (248 nm), an ArF excimer laser (193 nm), or an F2 excimer laser (157 nm). In an example embodiment, the light may be light in the extreme ultraviolet EUV wavelength range (13.5 nm).

The photomask 400 may include a transparent substrate 430 and a plurality of light-shielding patterns 410 formed in a plurality of light-shielding regions on the transparent substrate 430. The transparent substrate 430 may be formed of quartz. The plurality of light-shielding patterns 410 may be formed of chromium (Cr), but example embodiments are not limited thereto. A plurality of light-transmitting regions R¹ and light-shielding regions R² may be defined by the plurality of light-shielding patterns 410. The light-transmitting region R¹ is a region in which the light-shielding pattern 410 is not formed, while the light-shielding region R² is a region in which the light-shielding pattern 410 is formed.

The second resist layer 300 may include a first region 310 and a second region 330. A region exposed to light within the second resist layer 300 is the first region 310, while a region not exposed to light, for example, a region excluding the first region 310, is the second region 330. As the exposure process is performed, the bond between a central metal atom and an organic functional group of an organometallic compound present in the first region 310 may be cleaved. For example, at least a portion of the bonds between the central metal atom and two or more alkyl groups, aryl groups, or cycloalkyl groups covalently bonded to the central metal atom, among the organometallic compounds present in the first region 310, may be cleaved. The bond between the central metal atom and the one or more halide groups covalently bonded to the central metal atom may be maintained without being cleaved.

For example, when the organometallic compound includes a compound represented by Chemical Formula 1, the bond between tin (Sn), which is the central metal atom of the compound represented by Chemical Formula 1 present in the first region 310, and R¹ and/or R² may be cleaved.

Referring to FIGS. 1, 2, and 4C, removing an unexposed second region of the second resist layer by performing a heat treatment on the second resist layer to form a photoresist pattern (S40) may be performed. For example, a first heat treatment process may be performed. The first heat treatment process may be an operation of performing a heat treatment on the second resist layer to crosslink the first region (S41). The first heat treatment allows the central metal atom of the organometallic compound in the first region 310 to react with other organometallic compounds. For example, the first heat treatment process may be performed, allowing a crosslinking reaction between the organometallic compounds to occur. Accordingly, the first region 310 may be polymerized by the crosslinking reaction. As a result, a boiling point of the organometallic compound in the first region 310 may be increased.

Next, a second heat treatment process may be performed. The second heat treatment may be an operation of performing a second heat treatment on the second resist layer to remove the second region (S42). For example, the second heat treatment process may be performed by immediately increasing a temperature after the first heat treatment, and the photoresist composition in the second region 330 may be vaporized through the second heat treatment. Accordingly, the second region 330 of the second resist layer 300 may be removed. As a result, the photoresist pattern 300P may be formed.

In an example embodiment, the boiling point of the organometallic compound may be higher than a temperature at which the first heat treatment is performed, and lower than a temperature at which the second heat treatment is performed. The boiling point of the organometallic compound in the first region 310, in which the crosslinking reaction has occurred, may be higher than the temperature at which the secondary heat treatment is performed. For example, the boiling point of the organometallic compound may be about 200° C. to about 250° C., or any range therein. The first heat treatment may be performed, for example, at a temperature of about 110° C. to about 180° C., or any range therein. The second heat treatment may be performed, for example, at a temperature of about 200° C. to about 280° C., or any range therein.

In an example embodiment, the boiling point of the organometallic compound is higher than the temperature at which the first heat treatment is performed, so that the organometallic compound in the second region 330 may not be vaporized during the first heat treatment, and the crosslinking reaction may occur in the exposed first region 310. In some embodiments, the boiling point of the organometallic compound is lower than the temperature at which the secondary heat treatment is performed, so that the organometallic compound in the second region 330, which has a relatively low boiling point and does not undergo the crosslinking reaction, may be vaporized during the second heat treatment. Based on such a principle, a photoresist pattern may be formed without a development process. As a result, the process may be simplified, and defects caused by collapse of the photoresist pattern and residues of the photoresist pattern, which appear as the development process is performed, may be prevented.

Returning to FIG. 3, the photoresist pattern 300P may have a plurality of holes in plan view. Each of the holes may have a circular shape. The holes of the photoresist pattern 300P may be arranged in a honeycomb shape, but the shape of the holes is not limited thereto. For example, the shape of the holes of the photoresist pattern 300P may be changed to various shapes such as a zigzag shape, a polygonal shape, or a circular shape. Also, a planar shape of the photoresist pattern 300P may be variously changed. The photoresist pattern 300P may have, for example, a linear planar shape including portions extending in one direction.

The photoresist pattern 300P formed through the above-described process may not undergo pattern collapse even when a pattern having a high aspect ratio is formed. Accordingly, the photoresist pattern 300P may have a width of 5 nm to 100 nm, or any range therein. The photoresist pattern 300P may be formed to have a with a width of, for example, 5 nm to 90 nm, 5 nm to 80 nm, 5 nm to 70 nm, 5 nm to 60 nm, 5 nm to 50 nm, 5 nm to 40 nm, 5 nm to 30 nm, or 5 nm to 20 nm.

Referring to FIGS. 1 and 4D, processing the first resist layer using the photoresist pattern (S50) may be performed. An etching process may be performed to selectively etch the first resist layer 200. For example, the first resist layer 200 may be selectively etched in regions, which are not covered with the photoresist pattern 300P, using the photoresist pattern 300P as an etching mask. Thus, a lower pattern 200P may be formed. The lower pattern 200P may have a width corresponding to a width of the photoresist pattern 300P.

Referring to FIG. 4E, an etching process may be performed to etch an etching target. The etching process may be performed using the photoresist pattern 300P as an etching mask. For example, the substrate 100 may be etched using the photoresist pattern 300P as an etching mask through a dry or wet etching process. Accordingly, the photoresist pattern 300P and the lower pattern 200P may be removed through an additional etching process after the substrate 100 is etched.

A semiconductor device may be finally manufactured using the manufacturing method including the above-described operations.

In an example embodiment, unlike the above description, the process of forming the first resist layer may be omitted. In addition, various processes, such as a process of etching a thin film formed on the substrate using the photoresist pattern, a process of implanting impurity ions into a portion of the substrate, a process of forming an additional layer on the substrate through openings, or a process of modifying a portion of the substrate through openings, may be performed. The photoresist pattern formed based on the above-described operations may be used, for example, to form a vertical channel transistor of a DRAM.

As set forth above, according to example embodiments, a method of manufacturing a semiconductor device with a simplified process and improved productivity may be provided.

While example embodiments have been shown and described above, it will be apparent to those skilled in the art that modifications and variations could be made without departing from the scope of the present inventive concept as defined by the appended claims.

What is claimed is:

1. A method of manufacturing a semiconductor device, the method comprising:
forming a first resist layer on a substrate;
forming a second resist layer on the first resist layer;
exposing a first region of the second resist layer;
forming a photoresist pattern by performing a heat treatment on the second resist layer to remove an unexposed second region of the second resist layer; and
processing the first resist layer using the photoresist pattern.

2. The method of claim 1, wherein
the forming of the photoresist pattern comprises:
performing a first heat treatment on the second resist layer to crosslink the first region; and
performing a second heat treatment on the second resist layer to remove the second region.

3. The method of claim 2, wherein
the first heat treatment is performed at a lower temperature than the second heat treatment.

4. The method of claim 2, wherein
the second resist layer comprises an organometallic compound, an additive, and a solvent, and
a boiling point of the organometallic compound is higher than a temperature at which the first heat treatment is performed, and lower than a temperature at which the second heat treatment is performed.

5. The method of claim 4, wherein
the organometallic compound comprises:
a metal as a central atom;
two or more hydrocarbon groups covalently bonded to the metal; and
one or more F, Cl, Br, or I each covalently bonded to the metal,
the metal is selected from polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), or astatine (At), and
the hydrocarbon groups are each independently a substituted or unsubstituted C1-C12 alkyl group, a substituted or unsubstituted C5-C8 cycloalkyl group, or a substituted or unsubstituted C6-C14 aryl group.

6. The method of claim 5, wherein
the metal is tetravalent tin (Sn).

7. The method of claim 5, wherein
the organometallic compound comprises a compound represented by the following Chemical Formula 1: 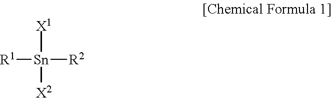
wherein R¹ and R² are each independently a substituted or unsubstituted C1-C12 alkyl group, a substituted or unsubstituted C5-C8 cycloalkyl group, or a substituted or unsubstituted C6-C14 aryl group, and
X¹ and X² are each independently one of F, Cl, Br, or I.

8. The method of claim 5, wherein
the organometallic compound comprises at least one compound selected from the following:

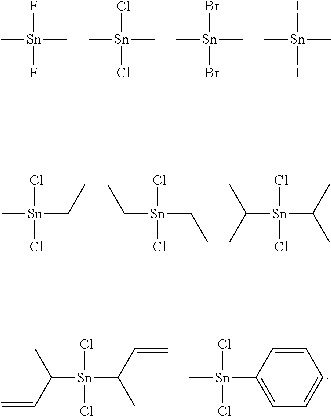

9. The method of claim 5, wherein
the organometallic compound comprises a compound represented by the following Chemical Formula 2: 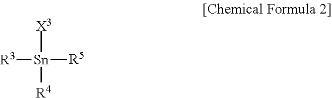
wherein R³, R⁴, and R⁵ are each independently a substituted or unsubstituted C1-C12 alkyl group, a substituted or unsubstituted C5-C8 cycloalkyl group, or a substituted or unsubstituted C6-C14 aryl group, and
X³ is F, Cl, Br, or I.

10. The method of claim 4, wherein
the solvent comprises at least one selected from an ether, an alcohol, a glycol ether, an aromatic hydrocarbon compound, a ketone, and an ester.

11. The method of claim 4, wherein
the additive comprises at least one selected from a crosslinker, a surfactant, a dispersant, a hygroscopic agent, or a coupling agent.

12. The method of claim 1, wherein
the exposing of the first region of the second resist layer is performed by extreme ultraviolet (EUV) light.

13. The method of claim 1, wherein
the second resist layer is non-chemically amplified.

14. A method of manufacturing a semiconductor device, the method comprising:
forming a first resist layer on a substrate;
forming a second resist layer on the first resist layer;
exposing a first region of the second resist layer;
performing a heat treatment on the second resist layer to form a photoresist pattern; and
processing an underlying layer using the photoresist pattern,
wherein
the forming of the photoresist pattern comprises:
performing a first heat treatment at a temperature of 110° C. to 180° C. to crosslink the first region and the first resist layer; and
performing a second heat treatment at a temperature of 200° C. to 280° C. to remove an unexposed second region of the second resist layer,
wherein the second resist layer comprises an organometallic compound, an additive, and a solvent,
the organometallic compound comprises:
two or more hydrocarbon groups covalently bonded to the metal; and
one or more F, Cl, Br, or I each covalently bonded to the metal,
the metal is polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), or astatine (At),
the hydrocarbon groups are each independently a substituted or unsubstituted C1-C12 alkyl group, a substituted or unsubstituted C5-C8 cycloalkyl group, or a substituted or unsubstituted C6-C14 aryl group, and
a boiling point of the organometallic compound is higher than a temperature at which the first heat treatment is performed, and lower than a temperature at which the second heat treatment is performed.

15. The method of claim 14, wherein
the metal is tetravalent tin (Sn).

16. The method of claim 14, wherein
the organometallic compound is a mixture of compounds represented by the following Chemical Formulas 1 and 2: 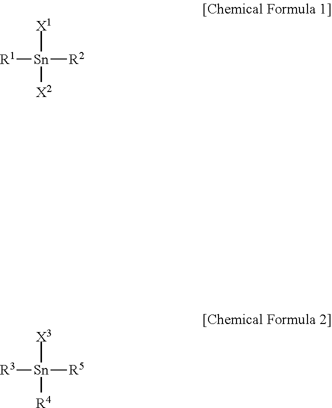
where R¹ to R⁵ are each independently a substituted or unsubstituted C1-C12 alkyl group, a substituted or unsubstituted C5-C8 cycloalkyl group, or a substituted or unsubstituted C6-C14 aryl group, and
X¹ to X³ are each independently one of s F, Cl, Br, or I.

17. A photoresist composition comprising:
an organometallic compound, an additive, and a solvent,
wherein
the organometallic compound comprises:
tetravalent tin (Sn) as a central metal atom;
two or more hydrocarbon groups covalently bonded to the tin; and
one or more F, Cl, Br, or I each covalently bonded to the tin, and
the hydrocarbon groups are each independently a substituted or unsubstituted C1-C12 alkyl group, a substituted or unsubstituted C5-C8 cycloalkyl group, or a substituted or unsubstituted C6-C14 aryl group.

18. The photoresist composition of claim 17, wherein
the organometallic compound comprises a compound represented by the following Chemical Formula 1: 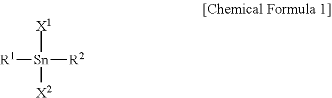
where R¹ and R² are each independently a substituted or unsubstituted C1-C12 alkyl group, a substituted or unsubstituted C5-C8 cycloalkyl group, or a substituted or unsubstituted C6-C14 aryl group, and
X¹ and X² are each independently F, Cl, Br, or I.

19. The photoresist composition of claim 17, wherein
the organometallic compound comprises at least one compound selected from the following:

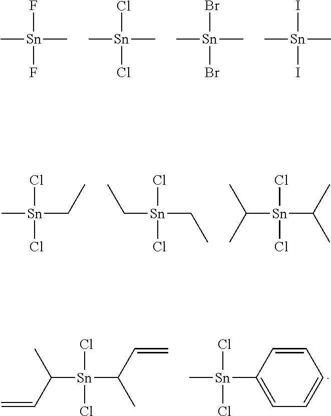

20. The photoresist composition of claim 17, wherein
the organometallic compound comprises a compound represented by the following Chemical Formula 2: 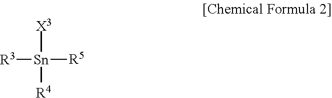
where R³, R⁴, and R⁵ are each independently a substituted or unsubstituted C1-C12 alkyl groups, a substituted or unsubstituted C5-C8 cycloalkyl group, or a substituted or unsubstituted C6-C14 aryl group, and
X³ is one of F, Cl, Br, and I.
